(19) United States
(12) Patent Application Publication
(10) Pub. No.: US 2006/0267127 A1
(43) Pub. Date: Nov. 30, 2006

(54) Semiconductor temperature sensor capable of adjusting sensed temperature

(75) Inventor: Yong-Jun Kim, Hwaseong-si (KR)

Correspondence Address: MILLS & ONELLO LLP, ELEVEN BEACON STREET, SUITE 605, BOSTON, MA, 02108, US

(73) Assignee: Samsung Electronics Co., Ltd.

(21) Appl. No.: 11/440,766

(22) Filed: May 25, 2006

(30) Foreign Application Priority Data
May 25, 2005 (KR) 10-2005-0044246

(51) Int. Cl. H01L 31/058; G05F 3/16; G05F 3/20

(52) U.S. Cl. 257/467; 323/315

(57) ABSTRACT

A temperature sensor can linearly adjust sensed temperature. The temperature sensor includes: a current generation circuit which generates a proportional-to-absolute temperature (PTAT) current and a conversely-proportional-to-absolute temperature (CTAT) current; and a temperature sensing unit which compares the PTAT current with the CTAT current, senses a temperature at which the PTAT current and the CTAT current are equal, increases the sensed temperature by reducing the PTAT current in response to a first control signal for controlling the sensed temperature to increase, decreases the sensed temperature by increasing the PTAT current in response to a second control signal for controlling the sensed temperature to decrease, and determines an adjustment amount of the sensed temperature which is increased or decreased in response to a third control signal for indicating the adjustment amount.

### BACKGROUND OF THE INVENTION

This application claims the priority of Korean Patent Application No. 10-2005-0044246, filed on May 25, 2005, in the Korean Intellectual Property Office, the disclosure of which is incorporated herein in its entirety by reference.

1. Field of the Invention

The present invention relates to a semiconductor device, and more particularly, to a semiconductor temperature sensor capable of sensing temperature of a semiconductor device and capable of adjusting the sensed temperature.

2. Description of the Related Art

Temperature sensors are used to sense ambient operational temperature of a circuit or device. They are particularly applicable when there is a need for adjusting operating conditions of circuit blocks within an integrated circuit in response to a change in ambient temperature.

For example, dynamic random access memories (DRAMs) must periodically refresh data stored in memory cells therein because the data is lost over time due to a leakage current from capacitors included in memory cells. A refresh cycle that is to short results in an unnecessary waste of current, and a refresh cycle that is too long results in data being lost. Therefore, the refresh cycle of memory cells should be optimized for data retention and power conservation. In addition, the time taken to store data in the memory cells depends on the operating temperature of a semiconductor memory device. Hence, a semiconductor device such as a DRAM commonly includes a temperature sensor and controls a circuit, for example, a circuit for controlling a refresh cycle in the case of a DRAM, in response to the operating temperature as sensed by the temperature sensor.

FIG. 1 is a circuit diagram of a conventional temperature sensor 10. Referring to FIG. 1, the temperature sensor 10 includes first through third PMOS transistors MP1 through MP3 connected to a first node 11, which, in turn, is connected to a voltage source. A first diode D1 is interposed between the first PMOS transistor MP1 and a ground source, a resistor RR and a second diode D2 are interposed between the second PMOS transistor MP2 and the ground source, and a resistor R1 is interposed between the third PMOS transistor MP3 and the ground source.

The temperature sensor 10 further includes a first amplifier AMP1 which differentially amplifies voltages of a second node 12 and a third node 13 and transmits the differentially amplified voltages to respective gates of the first and second PMOS transistors MP1 and MP2, a second amplifier AMP2 which differentially amplifies voltages of the third node 13 and a fourth node 14 and transmits the differentially amplified voltages to a gate of the third PMOS transistor MP3, and third and fourth comparators CP3 and CP4 which compare voltages of the first and second amplifiers AMP1 and AMP2 and output the comparison result.

The conventional temperature sensor 10 of FIG. 1 utilizes a bandgap reference voltage generation circuit well known to those of ordinary skill in the art. Reference current 1 (I=I₁=I₂) is generated based on current I₂ flowing from the second node 12 into the first diode D1 and current I₁ flowing from the third node 1₃ into the second diode D2.

When a ratio of the area of the first diode D1 to the second diode D2 is 1:n, the reference current I may be expressed as I=kT/q*1n(n)/RR, where k denotes the Boltzmann constant, T denotes absolute temperature, q denotes an electric charges, and RR denotes a value of the resistor RR. In other words, the reference current I increases in proportion to the absolute temperature T.

Current Iₓ flowing through the resistor R1 connected to the fourth node 14 may be expressed as Iₓ=V₁₂/R1, where V₁₂ denotes a voltage of the second node 12 or the fourth node 14. Since an increase in the absolute temperature T results in a decrease in the voltage V₁₂, the current Iₓ is in inverse proportion to the absolute temperature T.

FIG. 2 includes graphs that illustrate the characteristics of currents and voltages flowing in the temperature sensor 10 of FIG. 1 as functions of temperature. Referring to FIG. 2, the reference current I is a proportional-to-absolute temperature (PTAT) current, and the current Iₓ flowing through the resistance R1 is a conversely-proportional-to-absolute temperature (CTAT) current.

The third amplifier AMP3 and the fourth comparator CP4 of FIG. 1 compare an output voltage NOC0 of the first amplifier AMP1 with an output voltage NOC1 of the second amplifier AMP2 and output a comparison result TOUT.

In FIG. 2, the PTAT current, i.e., the reference current 1, corresponds to the output voltage NOC0 of the first amplifier AMP1, and the CTAT current, i.e., the current Iₓ, corresponds to the output voltage NOC1 of the second amplifier AMP2. The PTAT current and the CTAT current are equal to each other at a predetermined temperature T0. Hence, the third and fourth comparators CP3 and CP4 of FIG. 1 output the comparison result TOUT corresponding to whether the temperature of a semiconductor device exceeds the predetermined temperature T0.

FIG. 3 is a graph illustrating an output of the temperature sensor 10 of FIG. 1. Referring to FIG. 3, since the PTAT current is less than the CTAT current when the temperature of the semiconductor device does not exceed the predetermined temperature T0, the third comparator CP3 of FIG. 1 outputs a logic low signal. Conversely, since the PTAT current is larger than the CTAT current when the temperature of the semiconductor exceeds the predetermined temperature T0, the third comparator CP3 of FIG. 1 outputs a logic high signal.

FIG. 4 illustrates circuit diagrams of the third and fourth comparators CP3 and CP4 of FIG. 1. Referring to FIG. 4, the third comparator CP3 includes four PMOS transistors P41 through P44 and four NMOS transistors N41 through N44. The output voltage NOC0 of the first amplifier AMP1 is applied to gates of the first and fourth PMOS transistors P41 and P44, and the output voltage NOC1 of the second amplifier AMP2 is applied to gates of the second and third transistors P42 and P43. The fourth comparator CP4 converts differential outputs DIF and DIFB of the third comparator CP3 into a single-ended output TOUT.

The predetermined temperature T0 in FIGS. 2 and 3 is the sensed temperature of the semiconductor device and may be adjusted by changing the resistor R1 of FIG. 1. In other words, when the resistor R1 is adjusted, the CTAT current, i.e., the current Iₓ, in FIG. 1 changes. Accordingly, the point at which the PTAT current and the CTAT current are equal, and sensed temperature, are adjusted.

FIG. 5 is a graph illustrating variations in sensed temperature according to changes in resistance. In FIG. 5, it is assumed that the difference between resistors R51 and R52 is equal to the difference between resistors R53 and R54. When the resistance changes from R51 to R52, the sensed temperature is adjusted between T51 and T52 by ΔT1, and when the resistance changes from R53 to R54, the sensed temperature is adjusted between T53 and T64 by ΔT2. However, since ΔT1 and ΔT2 are different values, the sensed temperature cannot be linearly adjusted through resistance control.

### SUMMARY OF THE INVENTION

The present invention provides a temperature sensor that is capable of changing the sensed temperature, and further provides a temperature sensor that is capable of changing the sensed temperature in a linear manner.

According to an aspect of the present invention, there is provided a temperature sensor that senses operating temperature of a semiconductor device. The temperature sensor includes: an current generation circuit which generates a proportional-to-absolute temperature (PTAT) current and a conversely-proportional-to-absolute temperature (CTAT) current; and a temperature sensing unit which compares the PTAT current with the CTAT current, senses a temperature at which the PTAT current and the CTAT current are equal, increases the sensed temperature by reducing the PTAT current in response to a first control signal for controlling the sensed temperature to increase, and decreases the sensed temperature by increasing the PTAT current in response to a second control signal for controlling the sensed temperature to decrease.

In one embodiment, the temperature sensing unit may include: a sensed temperature adjuster which amplifies a difference between the PTAT current and the CTAT current and generates a first differential output signal and a second differential output signal a phase of which is opposite to a phase of the first differential output signal; and a comparator which compares the first differential output signal with the second differential output signal and generates one of a logic low signal and a logic high signal based on the comparison result.

In another embodiment, the current generation circuit comprises: first through third PMOS transistors connected in parallel to a voltage source; a first diode connected in series between the first PMOS transistor and a ground source; a first resistor connected in series to the second PMOS transistor; a second diode connected in series between the first resistor and the ground source; a second resistor connected in series between the third PMOS transistor and the ground source; a first differential amplifier comprising an invert input terminal connected to a connection node of the first PMOS transistor and the first diode, a non-invert input terminal connected to a connection node of the second PMOS transistor and the first resistor, and an output terminal connected to gates of the first and second PMOS transistors; and a second differential amplifier comprising an invert input terminal connected to a connection node of the second PMOS transistor and the first resistor, a non-invert input terminal connected to a connection node of the third PMOS transistor and the second resistor, and an output terminal connected to a gate of the third PMOS transistor, wherein the output terminal of the first differential amplifier is an output terminal of the PTAT current, and the output terminal of the second differential amplifier is an output terminal of the CTAT current.

In another embodiment, the first diode and the second diode have different voltage ratios.

In another embodiment, the sensed temperature adjuster may include: a first differential amplifier comprising an invert input terminal which receives the CTAT current, a non-invert input terminal which receives the PTAT current, and an output terminal which outputs the first differential output signal; a second differential amplifier comprising an invert input terminal which receives the PTAT current, a non-invert input terminal which receives the CTAT current, and an output terminal which outputs the second differential output signal; and an offset control circuit which receives the first and second control signals and generates an offset control signal for increasing or decreasing offsets of the first and second differential amplifiers in response to the first and second control signals.

In another embodiment, the offset control circuit may subtract a predetermined amount of current from the PTAT current within the first and second differential amplifiers in response to the first control signal and add the predetermined amount of current to the PTAT current within the first and second differential amplifiers.

In another embodiment, the first differential amplifier comprises: a first PMOS transistor having a gate which receives the PTAT current and a source which is connected to the voltage source; a second PMOS transistor having a gate which receives the CTAT current and a source which is connected to the voltage source; a first NMOS transistor connected in series between the first PMOS transistor and the ground source; and a second NMOS transistor connected in series between the second PMOS transistor and the ground source, wherein gates of the first and second NMOS transistors are connected to a first connection node of the first PMOS transistor and the first NMOS transistor, the offset control signal is transmitted to the first connection node, and the first differential output signal is transmitted from a second connection node of the second PMOS transistor and the second NMOS transistor. The second differential amplifier comprises: a third PMOS transistor having a gate which receives the CTAT current and a source which is connected to the voltage source; a fourth PMOS transistor having a gate which receives the PTAT current and a source which is connected to the voltage source; a third NMOS transistor connected in series between the third PMOS transistor and the ground voltage; and a fourth NMOS transistor connected in series between the fourth PMOS transistor and the ground source, wherein gates of the third and fourth NMOS transistors are connected to a fourth connection node of the fourth PMOS transistor and the fourth NMOS transistor, the offset control signal is transmitted to the fourth connection node of the fourth PMOS transistor and the fourth NMOS transistor, and the second differential output signal is transmitted from the fourth connection node.

In another embodiment, the offset control circuit comprises: fifth through eighth PMOS transistors having respective sources connected to the voltage source; and fifth through eighth NMOS transistors, each connected in series between each of the fifth through eighth PMOS transistors, respectively, and the ground source, wherein gates of the fifth and sixth PMOS transistors are connected to a connection node of the fifth PMOS transistor and the fifth NMOS transistor, gates of the seventh and eighth PMOS transistors are connected to a connection node of the eighth PMOS transistor and the eighth NMOS transistor, the second control signal is transmitted to gates of the fifth and eighth NMOS transistors, the first control signal is transmitted to gates of the sixth and seventh NMOS transistors, a connection node of the sixth PMOS transistor and the sixth NMOS transistor is connected to a connection node of the first PMOS transistor and the first NMOS transistor, and a connection node of the seventh PMOS transistor and the seventh NMOS transistor is connected to a connection node of the fourth PMOS transistor and the fourth NMOS transistor.

According to another aspect of the present invention, there is provided a temperature sensor that senses operating temperature of a semiconductor device. The temperature sensor includes: a current generation circuit which generates a proportional-to-absolute temperature (PTAT) current and a conversely-proportional-to-absolute temperature (CTAT) current; and a temperature sensing unit which compares the PTAT current with the CTAT current, senses a temperature at which the PTAT current and the CTAT current are equal, increases the sensed temperature by reducing the PTAT current in response to a first control signal for controlling the sensed temperature to increase, decreases the sensed temperature by increasing the PTAT current in response to a second control signal for controlling the sensed temperature to decrease, and determines an adjustment amount of the sensed temperature which is increased or decreased in response to a third control signal for indicating the adjustment amount.

In one embodiment, the temperature sensing unit may include: a sensed temperature adjuster which amplifies a difference between the PTAT current and the CTAT current and generates a first differential output signal and a second differential output signal a phase of which is opposite to a phase of the first differential output signal; and a comparator which compares the first differential output signal with the second differential output signal and generates one of a logic low signal and a logic high signal based on the comparison result.

In another embodiment the current generation circuit comprises: first through third PMOS transistors connected in parallel to a voltage source; a first diode connected in series between the first PMOS transistor and a ground source; a first resistor connected in series to the second PMOS transistor; a second diode connected in series between the first resistor and the ground source; a second resistor connected in series between the third PMOS transistor and the ground source; a first differential amplifier comprising an invert input terminal connected to a connection node of the first PMOS transistor and the first diode, a non-invert input terminal connected to a connection node of the second PMOS transistor and the first resistor, and an output terminal connected to gates of the first and second PMOS transistors; and a second differential amplifier comprising an invert input terminal connected to a connection node of the second PMOS transistor and the first resistor, a non-invert input terminal connected to a connection node of the third PMOS transistor and the second resistor, and an output terminal connected to a gate of the third PMOS transistor, wherein the output terminal of the first differential amplifier is an output terminal of the PTAT current, and the output terminal of the second differential amplifier is an output terminal of the CTAT current.

In another embodiment, the first diode and the second diode have different voltage ratios.

In another embodiment, the sensed temperature adjuster may include: a first differential amplifier comprising an invert input terminal which receives the CTAT current, a non-invert input terminal which receives the PTAT current, and an output terminal which outputs the first differential output signal; a second differential amplifier comprising an invert input terminal which receives the PTAT current, a non-invert input terminal which receives the CTAT current, and an output terminal which outputs the second differential output signal; an offset control circuit which receives the first and second control signals and generates an offset control signal for increasing or decreasing offsets of the first and second differential amplifiers in response to the first and second control signals; and an adjustment amount determiner which receives the third control signal and determines an amount by which the offsets of the first and second differential amplifiers are adjusted in response to the third control signal.

In another embodiment, the offset control circuit may subtract a predetermined amount of current from the PTAT current within the first and second differential amplifiers in response to the first control signal and add the predetermined amount of current to the PTAT current within the first and second differential amplifiers. The predetermined amount of current corresponds to the third control signal.

In another embodiment, the first differential amplifier comprises: a first PMOS transistor having a gate which receives the PTAT current and a source which is connected to the voltage source; a second PMOS transistor having a gate which receives the CTAT current and a source which is connected to the voltage source; a first NMOS transistor connected in series between the first PMOS transistor and the ground source; and a second NMOS transistor connected in series between the second PMOS transistor and the ground source, wherein gates of the first and second NMOS transistors are connected to a first connection node of the first PMOS transistor and the first NMOS transistor, the offset control signal is transmitted to the first connection node, and the first differential output signal is transmitted from a second connection node of the second PMOS transistor and the second NMOS transistor. The second differential amplifier comprises: a third PMOS transistor having a gate which receives the CTAT current and a source which is connected to the voltage source; a fourth PMOS transistor having a gate which receives the PTAT current and a source which is connected to the voltage source; a third NMOS transistor connected in series between the third PMOS transistor and the ground voltage; and a fourth NMOS transistor connected in series between the fourth PMOS transistor and the ground source, wherein gates of the third and fourth NMOS transistors are connected to a fourth connection node of the fourth PMOS transistor and the fourth NMOS transistor, the offset control signal is transmitted to the fourth connection node of the fourth PMOS transistor and the fourth NMOS transistor, and the second differential output signal is transmitted from the fourth connection node.

In another embodiment, the offset control circuit comprises: fifth through eighth PMOS transistors having respective sources connected to the voltage source; fifth and sixth NMOS transistors connected in series between the fifth PMOS transistor and the ground source; seventh and eighth NMOS transistors connected in series between the sixth PMOS transistor and the ground source; ninth and tenth NMOS transistors connected in series between the seventh PMOS transistor and the ground source; and

eleventh and twelfth NMOS transistors connected in series between the eighth PMOS transistor and the ground source, wherein gates of the fifth and sixth PMOS transistors are connected to a connection node of the fifth PMOS transistor and the fifth NMOS transistor, gates of the seventh and eighth PMOS transistors are connected to a connection node of the eighth PMOS transistor and the eleventh NMOS transistor, an output signal of the adjustment amount determiner is transmitted to gates of the fifth, seventh, ninth, and eleventh NMOS transistors, the second control signal is transmitted to gates of the sixth and twelfth NMOS transistors, the first control signal is transmitted to gates of the eighth and tenth NMOS transistors, a connection node of the sixth PMOS transistor and the seventh NMOS transistor is connected to a connection node of the first PMOS transistor and the first NMOS transistor, and a connection node of the seventh PMOS transistor and the ninth NMOS transistor is connected to a connection node of the fourth PMOS transistor and the fourth NMOS transistor.

In another embodiment, the adjustment amount determiner comprises: a first group of PMOS transistors connected in parallel, each having a gate which receives the PTAT current and a source which is connected to the voltage source; a second group of PMOS transistors respectively connected in series to the first group of PMOS transistors, each PMOS transistor having a gate which receives a signal corresponding to the third control signal; and a thirteenth NMOS transistor connected between a common drain of the second group of PMOS transistors and the ground source, wherein a gate of the thirteenth NMOS transistor is connected to the common drain of the second group of PMOS transistors and gates of the fifth, seventh, ninth, and eleventh NMOS transistors of the offset control circuit.

### BRIEF DESCRIPTION OF THE DRAWINGS

The above and other features and advantages of the present invention will become more apparent by describing in detail exemplary embodiments thereof with reference to the attached drawings in which:

FIG. 1 is a circuit diagram of a conventional temperature sensor;

FIG. 2 contains graphs that illustrate characteristics of currents and voltages in the temperature sensor of FIG. 1 according to an embodiment of the present invention;

FIG. 3 is a graph that illustrates an output of the temperature sensor of FIG. 1;

FIG. 4 includes circuit diagrams of the third and fourth comparators of FIG. 1;

FIG. 5 is a graph illustrating variations in sensed temperature according to changes in resistance;

FIG. 6 is a block diagram of a temperature sensor according to an embodiment of the present invention;

FIG. 7 is a circuit diagram of a sensed temperature adjustment unit of FIG. 6 according to an embodiment of the present invention;

FIG. 8 is a detailed circuit diagram of the sensed temperature adjustment unit of FIG. 7 according to an embodiment of the present invention;

FIG. 9 is a graph illustrating the relationship between variations in a proportional-to-absolute temperature (PTAT) current and sensed temperature according to an embodiment of the present invention;

FIG. 10 is a block diagram of a temperature sensor according to another embodiment of the present invention;

FIG. 11 is a circuit diagram of a sensed temperature adjustment unit of FIG. 10 according to an embodiment of the present invention;

FIG. 12 is a detailed circuit diagram of the sensed temperature adjustment unit of FIG. 11 according to an embodiment of the present invention; and

FIG. 13 is a graph illustrating the relationship between variations in a PTAT current and sensed temperature according to an embodiment of the present invention.

### DETAILED DESCRIPTION OF EMBODIMENTS OF THE INVENTION

The present invention will now be described more fully with reference to the accompanying drawings, in which exemplary embodiments of the invention are shown. The invention may, however, be embodied in many different forms and should not be construed as being limited to the embodiments set forth therein; rather, these embodiments are provided so that this disclosure will be thorough and complete. Like reference numerals in the drawings denote like elements, and thus their description will be omitted.

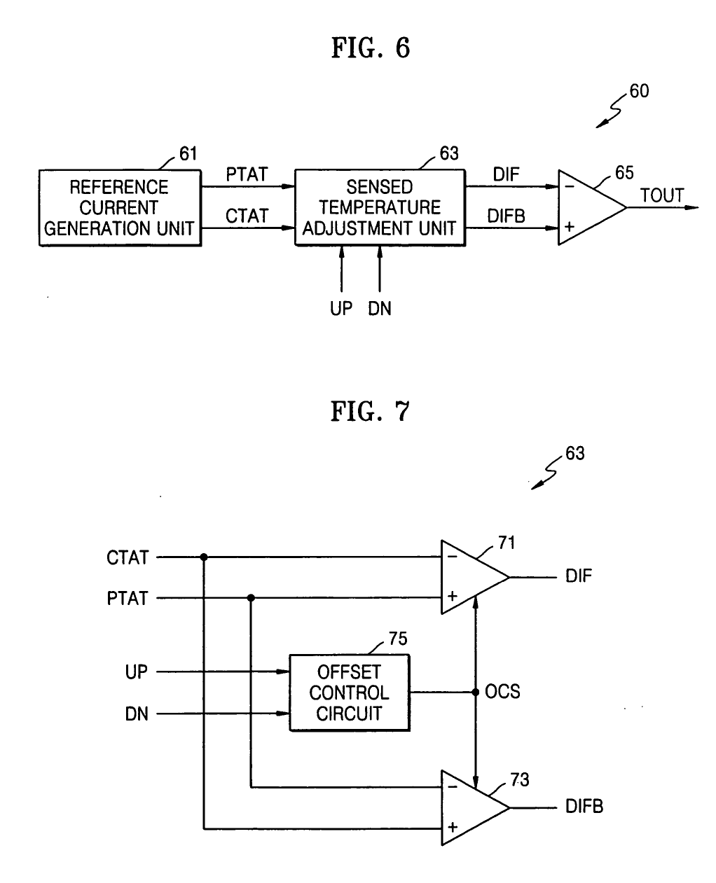

FIG. 6 is a block diagram of a temperature sensor 60 according to an embodiment of the present invention. The temperature sensor 60 includes a reference current generation unit 61, a sensed temperature adjustment unit 63, and a differential amplification unit 65.

The reference current generation unit 61 generates a proportional-to-absolute temperature (PTAT) current and a conversely-proportional-to-absolute temperature (CTAT) current. The sensed temperature adjustment unit 63 receives the PTAT current and the CTAT current, amplifies the difference between the PTAT current and the CTAT current, and outputs DIF and DIFB signals. In addition, the sensed temperature adjustment unit 63 receives an UP control signal for controlling the sensed temperature to increase and a DN control signal for controlling the sensed temperature to decrease and adjusts the sensed temperature. The differential amplification unit 65 compares the DIF and DIFB signals, and outputs a logic high signal if one of the DIF and DIFB signals is greater than the other one or outputs a logic low signal if otherwise. For example, if the DIF signal is greater than the DIFB signal, the differential amplification unit 65 outputs a logic low signal TOUT, and if the DIFB signal is greater than the DIF signal, the differential amplification unit 65 outputs a logic high signal TOUT.

In other words, instead of controlling resistance, the temperature sensor 60 uses the UP control signal and the DN control signal to linearly adjust the sensed temperature.

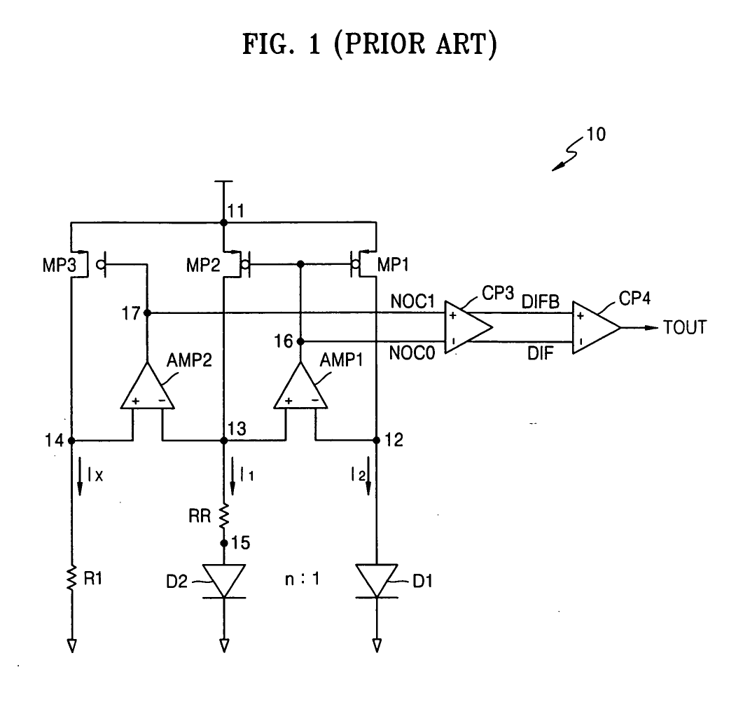

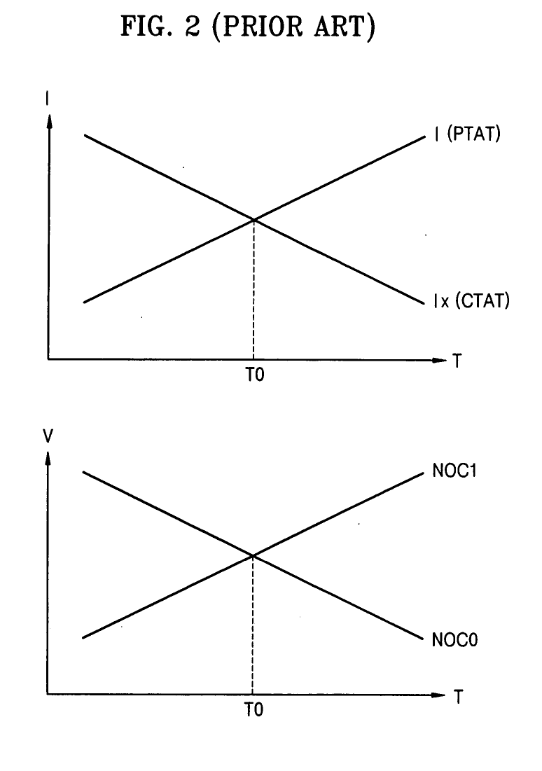

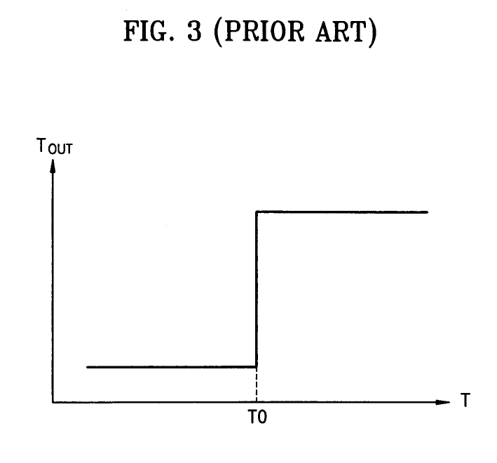

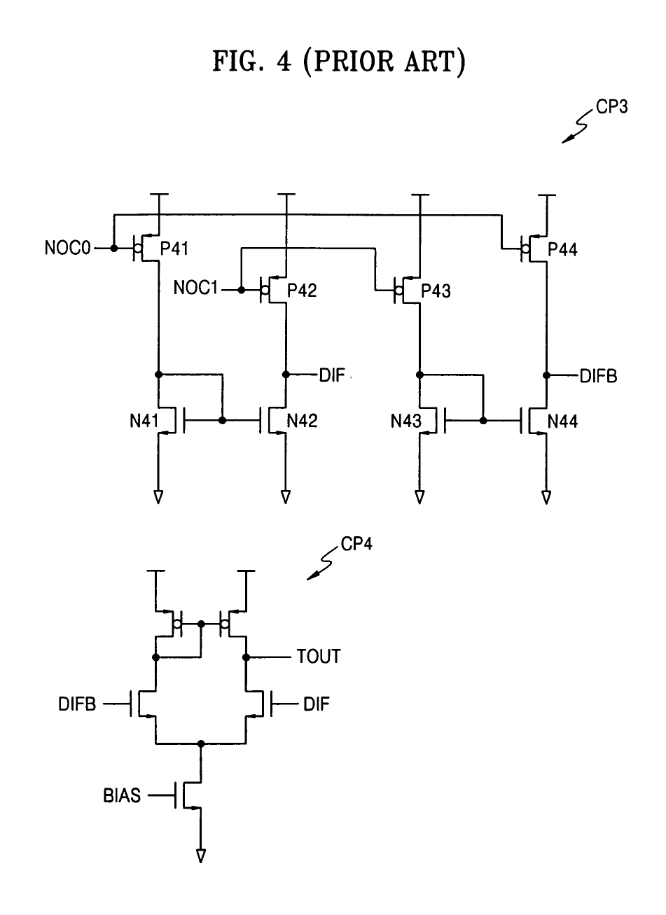

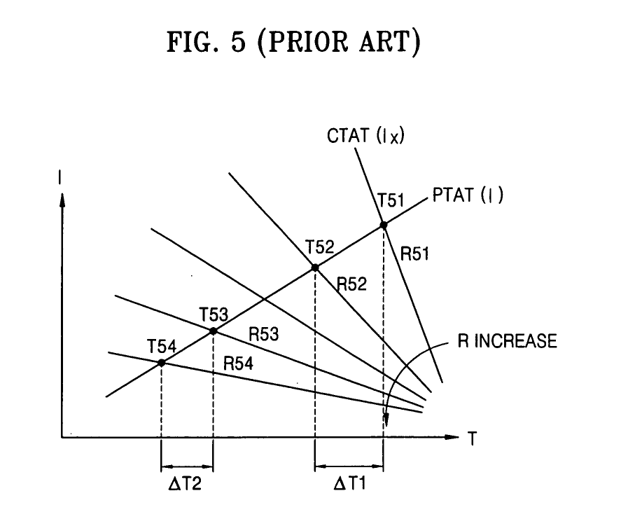

The reference current generation unit 61 of FIG. 6 may use the same circuit as that of the temperature sensor 10 of FIG. 1. That is, the reference current generation unit 61 of FIG. 6 may have a circuit configuration identical to that of the temperature sensor 10 of FIG. 1 excluding the third comparator CP3.

FIG. 7 is a circuit diagram of the sensed temperature adjustment unit 63 of FIG. 6 according to an embodiment of the present invention. Referring to FIG. 7, the sensed temperature adjustment unit 63 includes a first differential amplifier 71, a second differential amplifier 73, and an offset control circuit 75. The first and second differential amplifiers 71 and 73 receive the PTAT current and the CTAT current and respectively output the differentially amplified DIF and DIFB signals.

The offset control circuit 75 receives the UP or DN control signal, generates an offset control signal OCS for raising or lowering an amplifier offset in response to the UP or DN control signal, and outputs the offset control signal OCS to the first and second differential amplifiers 71 and 73.

The first and second differential amplifiers 71 and 73 add or subtract current corresponding to the offset control signal OCS to or from the PTAT current to adjust the sensed temperature. In other words, since the temperature at which the PTAT current and the CTAT current are equal increases or decreases in response to the offset control signal OCS, the sensed temperature is adjusted.

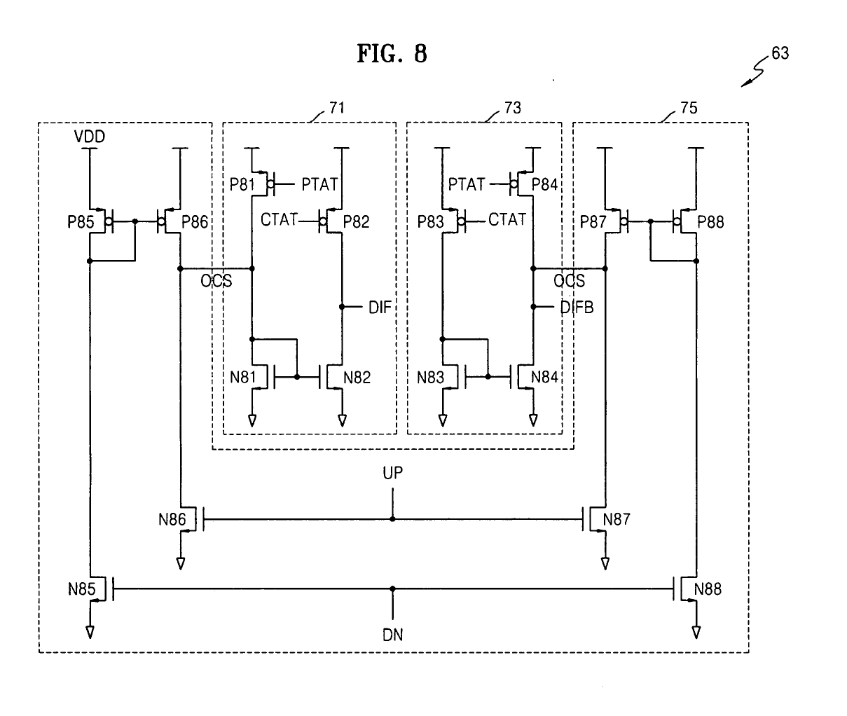

FIG. 8 is a detailed circuit diagram of the sensed temperature adjustment unit 63 of FIG. 7 according to an embodiment of the present invention. Referring to FIG. 8, the sensed temperature adjustment unit 63 includes first through eighth PMOS transistors P81 through P88 and first through eighth NMOS transistors N81 through N88.

The first differential amplifier 71 includes the first PMOS transistor P81 having a gate which receives the PTAT current and a source which is connected to a voltage source, the second PMOS transistor P82 having a gate which receives the CTAT current and a source which is connected to the voltage source, the first NMOS transistor N81 connected in series to the first PMOS transistor P81 and a ground source, and the second NMOS transistor N82 connected in series to the second PMOS transistor P82 and the ground source.

The gates of the first and second NMOS transistors N81 and N82 are connected to a connection node of the first PMOS transistor P81 and the first NMOS transistor N81. The offset control signal OCS output from the offset control circuit 75 is transmitted to the connection node of the first PMOS transistor P81 and the first NMOS transistor N81. A connection node of the second PMOS and NMOS transistors P82 and N82 is an output node of the DIF signal.

The second differential amplifier 73 includes the third PMOS transistor P83 having a gate which receives the CTAT current and a source which is connected to the voltage source, the fourth PMOS transistor P84 having a gate which receives the PTAT current and a source which is connected to the voltage source, the third NMOS transistor N83 connected in series to the third PMOS transistor P83 and the ground source, and the fourth NMOS transistor N84 connected in series to the fourth PMOS transistor P84 and the ground source.

The gates of the third and fourth NMOS transistors N83 and N84 are connected to a connection node of the third PMOS transistor P83 and the third NMOS transistor N83. The offset control signal OCS output from the offset control circuit 75 is transmitted to the connection node of the fourth PMOS transistor P84 and the fourth NMOS transistor N84. The connection node of the fourth PMOS and NMOS transistors P84 and N84 is an output node of the DIFB signal.

The offset control circuit 75 includes the fifth, sixth, seventh, and eighth PMOS transistors P85, P86, P87 and P88 having respective sources connected to the ground source, the fifth NMOS transistor N85 connected in series between the fifth PMOS transistor P85 and the ground source, the sixth NMOS transistor N86 connected in series between the sixth PMOS transistor P86 and the ground source, the seventh NMOS transistor N87 connected in series between the seventh PMOS transistor P87 and the ground source, and the eight NMOS transistor N88 connected in series between the eighth PMOS transistor P88 and the ground source.

Gates of the fifth and sixth PMOS transistors P85 and P86 are connected to a connection node of the fifth PMOS transistor P85 and the fifth NMOS transistor N85, and a connection node of the sixth PMOS transistor P86 and the sixth NMOS transistor N86 is an output node of the offset control signal OCS.

Gates of the seventh and eighth PMOS transistors P87 and P88 are connected to a connection node of the eighth PMOS transistor P88 and the eighth NMOS transistor N88, and a connection node of the seventh PMOS transistor P87 and the seventh NMOS transistor N87 is an output node of the offset control signal OCS.

The UP control signal is transmitted to gates of the sixth NMOS transistor N86 and the seventh NMOS transistor N87, the DN control signal is transmitted to gates of the fifth NMOS transistor N85 and the eighth NMOS transistor N88.

In response to the UP control signal, the sixth NMOS transistor N86 is turned on and the fifth NMOS transistor N85 is turned off. Thus, some current passing through the first PMOS transistor P81 leaks to the sixth NMOS transistor N86. In addition, the seventh NMOS transistor N87 is turned on and the eighth NMOS transistor N88 is turned off. Thus, some current passing through the fourth PMOS transistor P84 leaks to the seventh NMOS transistor N87. As a result, the PTAT current is reduced.

In response to the DN control signal, the fifth NMOS transistor N85 is turned on and the sixth NMOS transistor N86 is turned off. Thus, current passing through the sixth PMOS transistor P86 is added to the current passing through the first PMOS transistor P81 through an OCS terminal, and the added current flows to the first NMOS transistor N81. In addition, the eighth NMOS transistor N88 is turned on and the seventh NMOS transistor N87 is turned off. Thus, current passing through the seventh PMOS transistor P87 is added to the current passing through the fourth PMOS transistor P84, and the resultant current flows to the fourth NMOS transistor N84. As a result, the PTAT current increases.

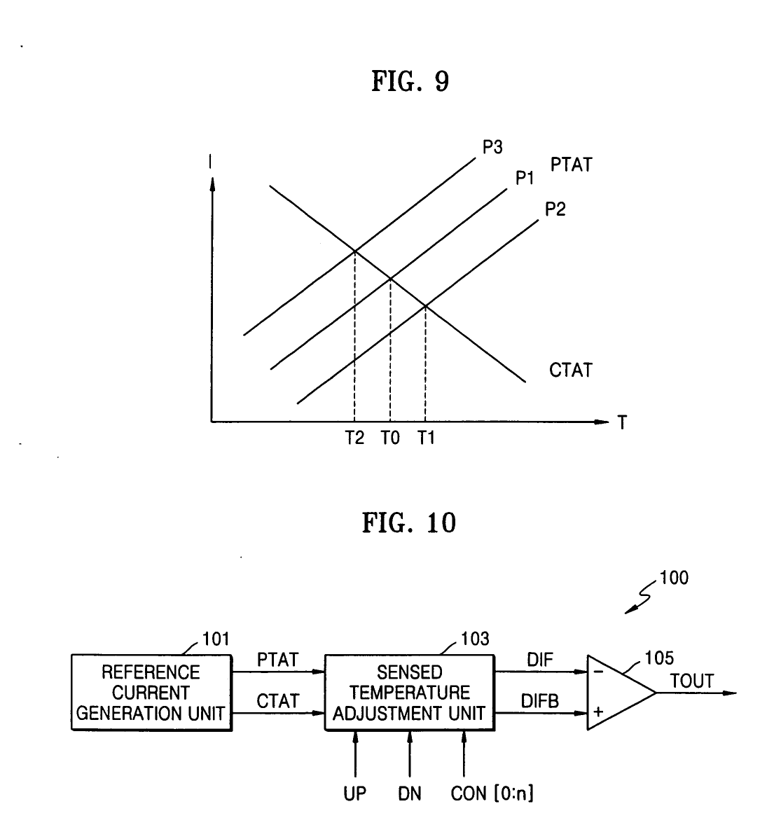

FIG. 9 is a graph illustrating the relationship between variations in the PTAT current and the sensed temperature according to an embodiment of the present invention. Referring to FIG. 9, when the UP control signal is transmitted to the gates of the sixth NMOS transistor N86 and the seventh NMOS transistor N87, the PTAT current is reduced from P1 to P2, thereby increasing the sensed temperature from T0 to T1.

When the DN control signal is transmitted to the gates of the fifth NMOS transistor N85 and the eighth NMOS transistor N88, the PTAT current increases from P1 to P3, thereby decreasing the sensed temperature from T0 to T2.

FIG. 10 is a block diagram of a temperature sensor 100 according to another embodiment of the present invention. Referring to FIG. 10, the temperature sensor 100 is similar to the temperature sensor 60 of FIG. 6. However, a sensed temperature adjustment unit 103 of the temperature sensor 100 of FIG. 10 further receives a control signal CON [0:n] indicating an adjustment amount by which the sensed temperature is increased or decreased and adjusts the adjustment amount of the sensed temperature accordingly. In other words, the sensed temperature adjustment unit 103 receives an UP control signal for controlling the sensed temperature to increase, a DN control signal for controlling the sensed temperature to decrease and the control signal CON [0:n] indicating the adjustment amount, and adjusts the sensed temperature accordingly.

Instead of using a resistance value to control the sensed temperature, the temperature sensor 100 of FIG. 10 uses the control signal CON [0:n], the UP control signal, and the DN control signal to linearly adjust the sensed temperature.

Like the reference current generation unit 61 of FIG. 6, a reference current generation unit 101 of FIG. 10 may also use a circuit identical to that of the temperature sensor 10 of FIG. 1.

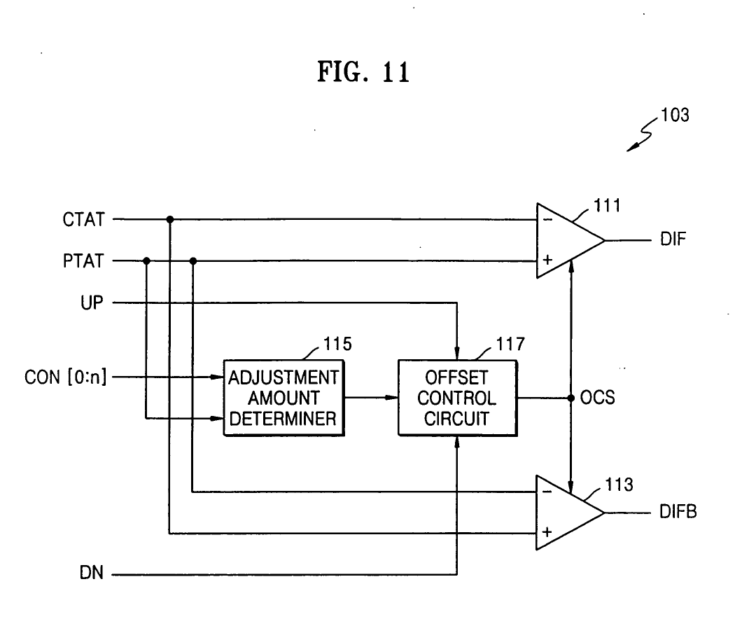

FIG. 11 is a circuit diagram of the sensed temperature adjustment unit 103 of FIG. 10 according to an embodiment of the present invention. Referring to FIG. 11, the sensed temperature adjustment unit 103 includes a first differential amplifier 111, a second differential amplifier 113, an adjustment amount determiner 115, and an offset control circuit 117. The first and second differential amplifiers 111 and 113 receive a PTAT current and a CTAT current and respectively output differentially amplified DIF and DIFB signals.

The adjustment amount determiner 115 receives the control signal CON [0:n], determines an amount of offset adjustment, and transmits the determined offset amount to the offset control circuit 117. The offset control circuit 117 receives the UP or DN control signal, generates an offset control signal OCS for raising or lowering an amplifier offset in response to the UP or DN control signal, and outputs the offset control signal OCS to the first and second differential amplifiers 111 and 113.

The first and second differential amplifiers 111 and 113 add or subtract current corresponding to the offset control signal OCS to or from the PTAT current to adjust the sensed temperature. In other words, since the temperature at which the PTAT current and the CTAT current are equal increases or decreases in response to the offset control signal OCS, the sensed temperature is adjusted.

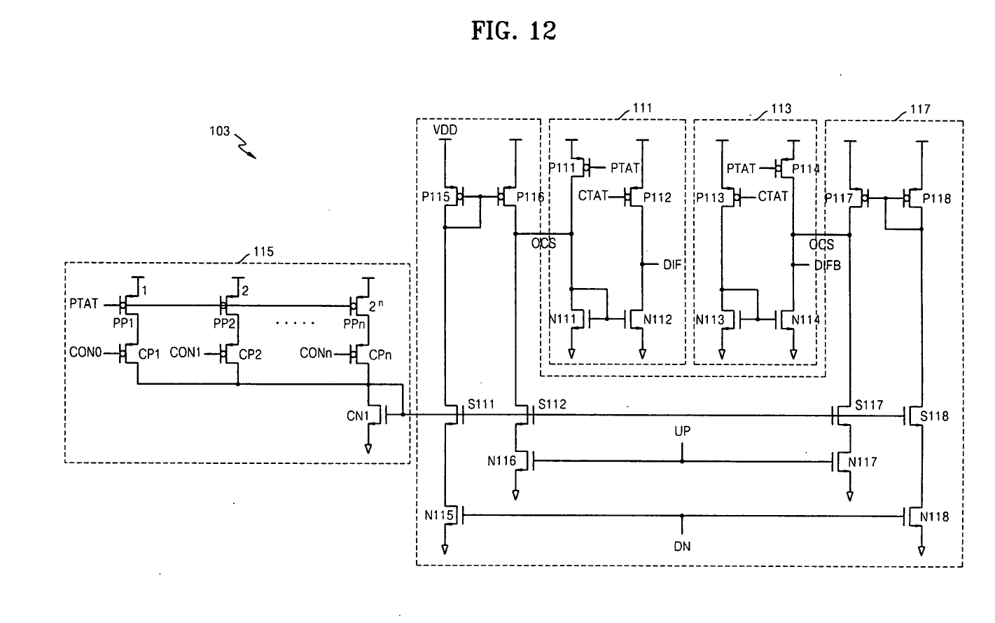

FIG. 12 is a detailed circuit diagram of the sensed temperature adjustment unit 103 of FIG. 11 according to an embodiment of the present invention. Referring to FIG. 12, the sensed temperature adjustment unit 103 includes first through eighth PMOS transistors P111 through P118, first through eighth NMOS transistors N111 through N118, and 2n PMOS transistors PP1 through PPn and CP1 through CPn, and five NMOS transistors CN1, S111, S112, S117, and S118.

The first differential amplifier 111 includes the first PMOS transistor P111 having a gate which receives the PTAT current and a source which is connected to a voltage source, the second PMOS transistor P112 having a gate which receives the CTAT current and a source which is connected to the voltage source, the first NMOS transistor N111 connected in series to the first PMOS transistor P111 and a ground source, and the second NMOS transistor N112 connected in series to the second PMOS transistor P112 and the ground source.

The gates of the first and second NMOS transistors N111 and N112 are connected to a connection node of the first PMOS transistor P111 and the first NMOS transistor N111. The offset control signal OCS output from the offset control circuit 117 is transmitted to the connection node of the first PMOS transistor P111 and the first NMOS transistor N111. A connection node of the second PMOS and NMOS transistors P112 and N112 is an output node of the DIF signal.

The second differential amplifier 113 includes the third PMOS transistor P113 having a gate which receives the CTAT current and a source which is connected to the voltage source, the fourth PMOS transistor P114 having a gate which receives the PTAT current and a source which is connected to the voltage source, the third NMOS transistor N113 connected in series to the third PMOS transistor P113 and the ground source, and the fourth NMOS transistor N114 connected in series to the fourth PMOS transistor P114 and the ground source.

The gates of the third and fourth NMOS transistors N113 and N114 are connected to a connection node of the third PMOS transistor P113 and the third NMOS transistor N113. The offset control signal OCS output from the offset control circuit 117 is transmitted to the connection node of the fourth PMOS transistor P114 and the fourth NMOS transistor N114. The connection node of the fourth PMOS and NMOS transistors P114 and N114 is an output node of the DIFB signal.

The adjustment amount determiner 115 includes a first group of n PMOS transistors PP1 through PPn connected in parallel, each having a gate which receives the PTAT current and a source which is connected to the voltage source, a second group of n PMOS transistors CP1 through CPn respectively connected in series to the first group of PMOS transistors PP1 through PPn, each one of the second group of PMOS transistors CPn having a gate which receives a signal corresponding to the control signal CON [0:n], and an NMOS transistor CN1 connected between a common drain of the second group of PMOS transistors CP1 through CPn and the ground source. The common drain of the second group of PMOS transistors CP1 through CPn is connected to a source and a gate of the NMOS transistor CN1.

In other words, in response to n control signals CON [0:n], each of the second group of PMOS transistors CP1 through CPn is turned on or off, thereby adjusting the amount of current flowing through the NMOS transistor CN1 to a desired level.

The offset control circuit 117 includes the fifth, sixth, seventh, and eighth PMOS transistors P115, P116, P117 and P118 having respective sources connected to the ground source, two NMOS transistors S111 and N115 connected in series between the fifth PMOS transistor P115 and the ground source, two NMOS transistors S112 and N116 connected in series between the sixth PMOS transistor P116 and the ground source, two NMOS transistors S117 and N117 connected in series between the seventh PMOS transistor P117 and the ground source, and two NMOS transistors S118 and N118 connected in series between the eighth PMOS transistor P118 and the ground source.

Gates of the fifth and sixth PMOS transistors P115 and P116 are connected to a connection node of the fifth PMOS transistor P115 and the NMOS transistor S111, and a connection node of the sixth PMOS transistor P116 and the NMOS transistor S112 is an output node of the offset control signal OCS.

Gates of the seventh and eighth PMOS transistors P117 and P118 are connected to a connection node of the eighth PMOS transistor P118 and the NMOS transistor S118, and a connection node of the seventh PMOS transistor P117 and the NMOS transistor S117 is an output node of the offset control signal OCS.

Each of gates of the NMOS transistors S111, S112, S117, and S118 is connected to a gate of the NMOS transistor CN1 of the adjustment amount determiner 115.

The UP control signal is transmitted to gates of the sixth NMOS transistor N116 and the seventh NMOS transistor N117, and the DN control signal is transmitted to gates of the fifth NMOS transistor N115 and the eighth NMOS transistor N118.

In response to the UP control signal, the sixth NMOS transistor N116 is turned on and the fifth NMOS transistor N115 is turned off. Thus, some of current passing through the first PMOS transistor P111 leaks to the sixth NMOS transistor N116. In addition, the seventh NMOS transistor N117 is turned on and the eighth NMOS transistor N118 is turned off. Thus, some of current passing through the fourth PMOS transistor P114 leaks to the seventh NMOS transistor N117. As a result, the PTAT current is reduced.

In the present embodiment, the PTAT current is reduced in proportion to the amount of current flowing through the NMOS transistor CN1 of the adjustment amount determiner 115. Hence, the amount by which the PTAT current is reduced can be adjusted by setting the control signal CON [0:n].

In response to the DN control signal, the fifth NMOS transistor N115 is turned on and the sixth NMOS transistor N116 is turned off. Thus, current passing through the sixth PMOS transistor P116 is added to the current passing through the first PMOS transistor P111 through an OCS terminal, and the resultant current flows to the first NMOS transistor N111. In addition, the eighth NMOS transistor N118 is turned on and the seventh NMOS transistor N117 is turned off. Thus, current passing through the seventh PMOS transistor P117 is added to the current passing through the fourth PMOS transistor P114, and the resultant current flows to the fourth NMOS transistor N114. As a result, the PTAT current increases.

Here, the PTAT current increases in proportion to the amount of current flowing through the NMOS transistor CN1 of the adjustment amount determiner 115. Hence, the amount by which the PTAT current increases can be adjusted by setting the control signal CON [0:n].

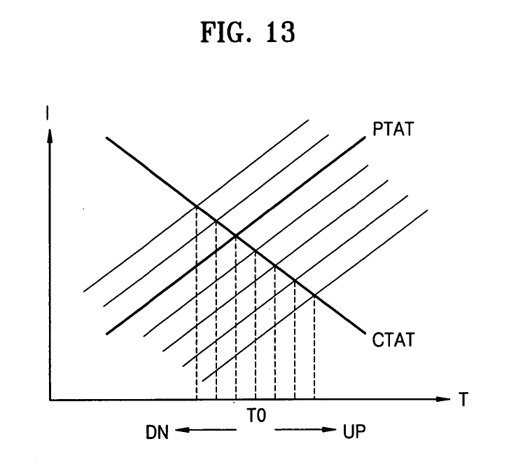

FIG. 13 is a graph illustrating the relationship between variations in the PTAT current and the sensed temperature. Referring to FIG. 13, the amount of current flowing inside the first and second differential amplifiers 111 and 113 is controlled using the UP control signal, the DN control signal, and the control signal CON [0:n]. In doing so, the offsets of the DIF and DIFB signals are output from the first and second differential amplifiers 111 and 113

When the UP control signal is transmitted to the gates of the sixth NMOS transistor N116 and the seventh NMOS transistor N117, the PTAT current is reduced as described above. Thus, the sensed temperature increases by an offset corresponding to the control signal CON [0:n].

When the DN control signal is transmitted to the gates of the fifth NMOS transistor N115 and the eighth NMOS transistor N118, the PTAT current increases. Thus, the sensed temperature decreases by an offset corresponding to the control signal CON [0:n].

The temperature sensor 100 can linearly control the sensed temperature using the control signal CON [0:n]. In other words, current corresponding to the control signal CON [0:n] flows in the adjustment amount determiner 115. In this case, the current may be linearly proportionate to the control signal CON [0:n]. Accordingly, current flowing in the offset adjustment circuit 117 is identical to the current flowing in the adjustment amount determiner 115, and the PTAT current subtracted or added in the first and second differential amplifiers 111 and 113 linearly corresponds to the current. Hence, the sensed temperature linearly corresponds to the control signal CON [0:n].

When a temperature is to be sensed using the temperature sensor 60 or 100, the amount of current is measured at any two temperatures and then a desired temperature and a value of current corresponding to the desired temperature can simply be obtained using a proportional expression.

As described above, a temperature sensor according to the present invention can linearly change sensed temperature. Thus, the temperature sensor can readily set a desired sensed temperature using a simple numerical expression.

While the present invention has been particularly shown and described with reference to exemplary embodiments thereof, it will be understood by those of ordinary skill in the art that various changes in form and details may be made therein without departing from the spirit and scope of the present invention as defined by the following claims.

What is claimed is:

1. A temperature sensor that senses operating temperature of a semiconductor device, the temperature sensor comprising:
an current generation circuit which generates a proportional-to-absolute temperature (PTAT) current and a conversely-proportional-to-absolute temperature (CTAT) current; and
a temperature sensing unit which senses a temperature at which the PTAT current and the CTAT current are equal, increases the sensed temperature by reducing the PTAT current in response to a first control signal for controlling the sensed temperature to increase, and decreases the sensed temperature by increasing the PTAT current in response to a second control signal for controlling the sensed temperature to decrease.

2. The temperature sensor of claim 1, wherein the temperature sensing unit comprises:
a sensed temperature adjuster which amplifies a difference between the PTAT current and the CTAT current and generates a first differential output signal and a second differential output signal a phase of which is opposite to a phase of the first differential output signal; and
a comparator which compares the first differential output signal with the second differential output signal and generates one of a logic low signal and a logic high signal based on the comparison result.

3. The temperature sensor of claim 2, wherein the current generation circuit comprises:
first through third PMOS transistors connected in parallel to a voltage source;
a first diode connected in series between the first PMOS transistor and a ground source;
a first resistor connected in series to the second PMOS transistor;
a second diode connected in series between the first resistor and the ground source;
a second resistor connected in series between the third PMOS transistor and the ground source;
a first differential amplifier comprising an invert input terminal connected to a connection node of the first PMOS transistor and the first diode, a non-invert input terminal connected to a connection node of the second PMOS transistor and the first resistor, and an output terminal connected to gates of the first and second PMOS transistors; and
a second differential amplifier comprising an invert input terminal connected to a connection node of the second PMOS transistor and the first resistor, a non-invert input terminal connected to a connection node of the third PMOS transistor and the second resistor, and an output terminal connected to a gate of the third PMOS transistor,
wherein the output terminal of the first differential amplifier is an output terminal of the PTAT current, and the output terminal of the second differential amplifier is an output terminal of the CTAT current.

4. The temperature sensor of claim 3, wherein the first diode and the second diode have different voltage ratios.

5. The temperature sensor of claim 2, wherein the sensed temperature adjuster comprises:
a first differential amplifier comprising an invert input terminal which receives the CTAT current, a non-invert input terminal which receives the PTAT current, and an output terminal which outputs the first differential output signal;
a second differential amplifier comprising an invert input terminal which receives the PTAT current, a non-invert input terminal which receives the CTAT current, and an output terminal which outputs the second differential output signal; and
an offset control circuit which receives the first and second control signals and generates an offset control signal for increasing or decreasing offsets of the first and second differential amplifiers in response to the first and second control signals.

6. The temperature sensor of claim 5, wherein the offset control circuit subtracts a predetermined amount of current from the PTAT current within the first and second differential amplifiers in response to the first control signal and adds the predetermined amount of current to the PTAT current within the first and second differential amplifiers.

7. The temperature sensor of claim 5, wherein
the first differential amplifier comprises:
a first PMOS transistor having a gate which receives the PTAT current and a source which is connected to the voltage source;
a second PMOS transistor having a gate which receives the CTAT current and a source which is connected to the voltage source;
a first NMOS transistor connected in series between the first PMOS transistor and the ground source; and
a second NMOS transistor connected in series between the second PMOS transistor and the ground source,
wherein gates of the first and second NMOS transistors are connected to a first connection node of the first PMOS transistor and the first NMOS transistor, the offset control signal is transmitted to the first connection node, and the first differential output signal is transmitted from a second connection node of the second PMOS transistor and the second NMOS transistor,
and wherein the second differential amplifier comprises:
a third PMOS transistor having a gate which receives the CTAT current and a source which is connected to the voltage source;
a fourth PMOS transistor having a gate which receives the PTAT current and a source which is connected to the voltage source;
a third NMOS transistor connected in series between the third PMOS transistor and the ground voltage; and
a fourth NMOS transistor connected in series between the fourth PMOS transistor and the ground source,
wherein gates of the third and fourth NMOS transistors are connected to a fourth connection node of the fourth PMOS transistor and the fourth NMOS transistor, the offset control signal is transmitted to the fourth connection node of the fourth PMOS transistor and the fourth NMOS transistor, and the second differential output signal is transmitted from the fourth connection node.

8. The temperature sensor of claim 7, wherein the offset control circuit comprises:
fifth through eighth PMOS transistors having respective sources connected to the voltage source; and
fifth through eighth NMOS transistors, each connected in series between each of the fifth through eighth PMOS transistors, respectively, and the ground source,
wherein gates of the fifth and sixth PMOS transistors are connected to a connection node of the fifth PMOS transistor and the fifth NMOS transistor, gates of the seventh and eighth PMOS transistors are connected to a connection node of the eighth PMOS transistor and the eighth NMOS transistor, the second control signal is transmitted to gates of the fifth and eighth NMOS transistors, the first control signal is transmitted to gates of the sixth and seventh NMOS transistors, a connection node of the sixth PMOS transistor and the sixth NMOS transistor is connected to a connection node of the first PMOS transistor and the first NMOS transistor, and a connection node of the seventh PMOS transistor and the seventh NMOS transistor is connected to a connection node of the fourth PMOS transistor and the fourth NMOS transistor.

9. A temperature sensor that senses operating temperature of a semiconductor device, the temperature sensor comprising:
a current generation circuit which generates a proportional-to-absolute temperature (PTAT) current and a conversely-proportional-to-absolute temperature (CTAT) current; and
a temperature sensing unit which compares the PTAT current with the CTAT current, senses a temperature at which the PTAT current and the CTAT current are equal, increases the sensed temperature by reducing the PTAT current in response to a first control signal for controlling the sensed temperature to increase, decreases the sensed temperature by increasing the PTAT current in response to a second control signal for controlling the sensed temperature to decrease, and determines an adjustment amount of the sensed temperature which is increased or decreased in response to a third control signal for indicating the adjustment amount.

10. The temperature sensor of claim 9, wherein the temperature sensing unit comprises:
a sensed temperature adjuster which amplifies a difference between the PTAT current and the CTAT current and generates a first differential output signal and a second differential output signal a phase of which is opposite to a phase of the first differential output signal; and
a comparator which compares the first differential output signal with the second differential output signal and generates one of a logic low signal and a logic high signal based on the comparison result.

11. The temperature sensor of claim 10, wherein the current generation circuit comprises:
first through third PMOS transistors connected in parallel to a voltage source;
a first diode connected in series between the first PMOS transistor and a ground source;
a first resistor connected in series to the second PMOS transistor;
a second diode connected in series between the first resistor and the ground source;
a second resistor connected in series between the third PMOS transistor and the ground source;
a first differential amplifier comprising an invert input terminal connected to a connection node of the first PMOS transistor and the first diode, a non-invert input terminal connected to a connection node of the second PMOS transistor and the first resistor, and an output terminal connected to gates of the first and second PMOS transistors; and
a second differential amplifier comprising an invert input terminal connected to a connection node of the second PMOS transistor and the first resistor, a non-invert input terminal connected to a connection node of the third PMOS transistor and the second resistor, and an output terminal connected to a gate of the third PMOS transistor,
wherein the output terminal of the first differential amplifier is an output terminal of the PTAT current, and the output terminal of the second differential amplifier is an output terminal of the CTAT current.

12. The temperature sensor of claim 11, wherein the first diode and the second diode have different voltage ratios.

13. The temperature sensor of claim 10, wherein the sensed temperature adjuster comprises:
a first differential amplifier comprising an invert input terminal which receives the CTAT current, a non-invert input terminal which receives the PTAT current, and an output terminal which outputs the first differential output signal;
a second differential amplifier comprising an invert input terminal which receives the PTAT current, a non-invert input terminal which receives the CTAT current, and an output terminal which outputs the second differential output signal;
an offset control circuit which receives the first and second control signals and generates an offset control signal for increasing or decreasing offsets of the first and second differential amplifiers in response to the first and second control signals; and
an adjustment amount determiner which receives the third control signal and determines an amount by which the offsets of the first and second differential amplifiers are adjusted in response to the third control signal.

14. The temperature sensor of claim 13, wherein the offset control circuit subtracts a predetermined amount of current from the PTAT current within the first and second differential amplifiers in response to the first control signal and adds the predetermined amount of current to the PTAT current within the first and second differential amplifiers.

15. The temperature sensor of claim 14, wherein the predetermined amount of current corresponds to the third control signal.

16. The temperature sensor of claim 13, wherein
the first differential amplifier comprises:
a first PMOS transistor having a gate which receives the PTAT current and a source which is connected to the voltage source;
a second PMOS transistor having a gate which receives the CTAT current and a source which is connected to the voltage source;
a first NMOS transistor connected in series between the first PMOS transistor and the ground source; and
a second NMOS transistor connected in series between the second PMOS transistor and the ground source,
wherein gates of the first and second NMOS transistors are connected to a first connection node of the first PMOS transistor and the first NMOS transistor, the offset control signal is transmitted to the first connection node, and the first differential output signal is transmitted from a second connection node of the second PMOS transistor and the second NMOS transistor,
and wherein the second differential amplifier comprises:
a third PMOS transistor having a gate which receives the CTAT current and a source which is connected to the voltage source;
a fourth PMOS transistor having a gate which receives the PTAT current and a source which is connected to the voltage source;
a third NMOS transistor connected in series between the third PMOS transistor and the ground voltage; and
a fourth NMOS transistor connected in series between the fourth PMOS transistor and the ground source,
wherein gates of the third and fourth NMOS transistors are connected to a fourth connection node of the fourth PMOS transistor and the fourth NMOS transistor, the offset control signal is transmitted to the fourth connection node of the fourth PMOS transistor and the fourth NMOS transistor, and the second differential output signal is transmitted from the fourth connection node.

17. The temperature sensor of claim 16, wherein the offset control circuit comprises:
fifth through eighth PMOS transistors having respective sources connected to the voltage source;
fifth and sixth NMOS transistors connected in series between the fifth PMOS transistor and the ground source;
seventh and eighth NMOS transistors connected in series between the sixth PMOS transistor and the ground source;
ninth and tenth NMOS transistors connected in series between the seventh PMOS transistor and the ground source; and
eleventh and twelfth NMOS transistors connected in series between the eighth PMOS transistor and the ground source,
wherein gates of the fifth and sixth PMOS transistors are connected to a connection node of the fifth PMOS transistor and the fifth NMOS transistor, gates of the seventh and eighth PMOS transistors are connected to a connection node of the eighth PMOS transistor and the eleventh NMOS transistor, an output signal of the adjustment amount determiner is transmitted to gates of the fifth, seventh, ninth, and eleventh NMOS transistors, the second control signal is transmitted to gates of the sixth and twelfth NMOS transistors, the first control signal is transmitted to gates of the eighth and tenth NMOS transistors, a connection node of the sixth PMOS transistor and the seventh NMOS transistor is connected to a connection node of the first PMOS transistor and the first NMOS transistor, and a connection node of the seventh PMOS transistor and the ninth NMOS transistor is connected to a connection node of the fourth PMOS transistor and the fourth NMOS transistor.

18. The temperature sensor of claim 17, wherein the adjustment amount determiner comprises:
a first group of PMOS transistors connected in parallel, each having a gate which receives the PTAT current and a source which is connected to the voltage source;
a second group of PMOS transistors respectively connected in series to the first group of PMOS transistors, each PMOS transistor having a gate which receives a signal corresponding to the third control signal; and
a thirteenth NMOS transistor connected between a common drain of the second group of PMOS transistors and the ground source,
wherein a gate of the thirteenth NMOS transistor is connected to the common drain of the second group of PMOS transistors and gates of the fifth, seventh, ninth, and eleventh NMOS transistors of the offset control circuit.
